(19) United States
(12) Patent Application Publication
(10) Pub. No.: US 2014/0022030 A1
(43) Pub. Date: Jan. 23, 2014

(54) SIGNAL TRANSMISSION CIRCUIT AND SIGNAL TRANSMISSION CELL THEREOF

(71) Applicant: NATIONAL TAIWAN UNIVERSITY, Taipei City (TW)

(72) Inventors: TZONG-LIN WU, TAIPEI CITY (TW); CHIH-YING HSIAO, TAIPEI CITY (TW); CHUNG-HAO TSAI, TAIPEI CITY (TW)

(73) Assignee: NATIONAL TAIWAN UNIVERSITY, TAIPEI CITY (TW)

(21) Appl. No.: 13/730,888

(22) Filed: Dec. 29, 2012

(30) Foreign Application Priority Data
Jul. 20, 2012 (TW) 101126233

(51) Int. Cl. H03H 7/01

(52) U.S. Cl. CPC H03H 7/01
USPC 333/170; 333/175; 333/185

(57) ABSTRACT

An exemplary embodiment of the present disclosure illustrates a signal transmission cell having a first through third conductors, a capacitor and an inductor. The first and third conductors form a first transmission circuit, and the second and the third conductors form a second transmission circuit. Signals which are respectively conveyed on the first transmission circuit and the second transmission circuit have the same magnitude, but have the opposite phases to each other, so as to form a pair of differential transmission lines. A first end of the inductor is electrically connected to the third conductor, and a second end of the inductor is electrically connected to a ground voltage. A first end of the capacitor is electrically connected to the first end of the inductor, and a second end of the capacitor is electrically connected to the second end the inductor.

### BACKGROUND

1. Technical Field

The present disclosure relates to a signal transmission circuit, in particular, to a signal transmission circuit and a signal transmission cell thereof capable of suppressing the common mode noise.

2. Description of Related Art

With the rapid advancement of the electronic technology, the higher operation rate and the clock frequency of the high speed digital circuit is required. Thus, it is essential that the differential microsrtip or stripline is adopted as the signal transmission medium.

Ideally, the differential transmission line has the higher noise resistance, the lower electromagnetic radiation, and the lower crosstalk. However, in the practical electronic circuit design, portion of differential mode signal may be converted to the common mode noise due to the unavoidable asymmetric structure or asymmetry of the signal magnitude and phase when the signal is outputted. For example, to save the area, an asymmetric layout, a corner, a via, and a slot may be used, and thus a symmetric structure is generated correspondingly. The common mode noise may be transmitted to the edge of the circuit board, the connection conductor or shielding metal through the ground plane, which causes the serious electromagnetic compatibility (EMC) and electromagnetic interference (EMI) problem.

The ferrite material of the common mode choke has the high inductance, and thus the common mode choke is adopted to suppress the generation of the common mode noise. However, since the permeability of the magnetic ferrite material decreases rapidly at the high frequency, the common mode choke is not suitable for the high speed signal interface with ten giga hertz (10 GHz).

Additionally, a resonant cavity of a defected ground structure or a mushroom structure is currently used to suppress the common mode noise. However, since the reference return paths of the differential mode transmission and the common mode transmission are different, a defected ground structure or a mushroom structure merely has wideband suppression for the common mode noise in the range at about several ten giga hertz.

The defected ground structure or the mushroom structure is implemented on the printed substrate or ceramics substrate via the surface mount device (SMD) technology, or directly embedded to the printed substrate or ceramics substrate. Recently, the planar miniaturization is approaching to the limitation, and thus the vertical integration becomes one tend of the miniaturization, such that the extra substrate area is reduced.

### SUMMARY

An exemplary embodiment of the present disclosure provides a signal transmission cell comprising a two-port all pass network and a common mode noise suppression circuit. The two-port all pass network comprises a first inductor, a second inductor, a first mutual capacitor, a third inductor, a fourth inductor, a second mutual capacitor, a first capacitor, and a second capacitor. A first end of the second inductor is electrically connected to a second end of the first inductor. A first and a second ends of the first mutual capacitor are respectively electrically connected to a first end of the first inductor and a second end of the second inductor. A first end of the fourth inductor is electrically connected to a second end of the third inductor. A first and a second ends of the second mutual capacitor are respectively electrically connected to a first end of the third inductor and a second end of the fourth inductor. A first end of the first capacitor is electrically connected to the first end of the second inductor. A first end of the second capacitor is electrically connected to a first end of the fourth inductor, and a second end of the second capacitor is electrically connected to a second end of the first capacitor. The common mode noise suppression circuit comprises a fifth inductor and a third capacitor. A first end of the fifth inductor is electrically connected to the second end of the first capacitor, and a second end of the fifth inductor is electrically connected to a ground voltage. A first end of the third capacitor is electrically connected to a first end of the fifth inductor, and a second end of the third capacitor is electrically connected to the ground voltage.

An exemplary embodiment of the present disclosure provides a signal transmission cell comprising a first through third conductors, a capacitor and an inductor. The first and third conductors form a first transmission circuit, and the second and the third conductors form a second transmission circuit. Signals which are respectively conveyed on the first transmission circuit and the second transmission circuit have the same magnitude, but have the opposite phases to each other, so as to form a pair of differential transmission lines. A first end of the inductor is electrically connected to the third conductor, and a second end of the inductor is electrically connected to a ground voltage. A first end of the capacitor is electrically connected to the first end of the inductor, and a second end of the capacitor is electrically connected to the second end the inductor.

An exemplary embodiment of the present disclosure provides a signal transmission circuit, wherein the signal transmission circuit comprises at least one signal transmission cell mentioned above.

To sum up, exemplary embodiments of the present disclosure provide a signal transmission circuit and a signal transmission cell thereof capable of suppressing the common mode noise.

In order to further understand the techniques, means and effects the present disclosure, the following detailed descriptions and appended drawings are hereby referred, such that, through which, the purposes, features and aspects of the present disclosure can be thoroughly and concretely appreciated; however, the appended drawings are merely provided for reference and illustration, without any intention to be used for limiting the present disclosure.

### BRIEF DESCRIPTION OF THE DRAWINGS

The accompanying drawings are included to provide a further understanding of the present disclosure, and are incorporated in and constitute a part of this specification. The drawings illustrate exemplary embodiments of the present disclosure and, together with the description, serve to explain the principles of the present disclosure.

FIG. 1A is a circuit diagram of a signal transmission cell according to an exemplary embodiment of the present disclosure.

FIG. 1B is a circuit diagram of a signal transmission cell according to another exemplary embodiment of the present disclosure.

FIG. 1C is a circuit diagram of a signal transmission cell according to another exemplary embodiment of the present disclosure.

FIG. 2A is a circuit diagram of a differential mode half circuit of a signal transmission cell of FIG. 1A which the mutual capacitors Cₘ₁ and Cₘ₂ are removed.

FIG. 2B is a circuit diagram of a differential mode half circuit of a signal transmission cell of FIG. 1A.

FIG. 2C is a curve diagram showing the relation between a frequency and S parameter |S_{dd21}|associated with the signal transmission cell of FIG. 1A and the signal transmission cell of FIG. 1A which the mutual capacitors Cₘ₁ and C are removed.

FIG. 3A is a circuit diagram of a common mode half circuit of a signal transmission cell of FIG. 1A which the capacitor Cₚ is removed.

FIG. 3B is a circuit diagram of a common mode half circuit of a signal transmission cell of FIG. 1A.

FIG. 3C is a curve diagram showing the relation between a frequency and S parameter |S_{cc21}| associated with the signal transmission cell of FIG. 1A and the signal transmission cell of FIG. 1A which the capacitor Cₚ is removed.

FIG. 4A and FIG. 4B are circuit diagrams of two signal transmission cells respectively according to another two exemplary embodiments of the present disclosure.

FIG. 4C is a curve diagram showing the relation between a frequency and S parameter |S₂₁| associated with the signal transmission cells of FIG. 1A, FIG. 4A, and FIG. 4B.

FIG. 4D is a curve diagram showing the relation between a frequency and an absorption associated with the signal transmission cells of FIG. 1A, FIG. 4A, and FIG. 4B.

FIG. 5A through FIG. 5C are circuit diagrams of three signal transmission cells respectively according to another three exemplary embodiments of the present disclosure.

FIG. 5D is an eye pattern of the differential mode signal associated with the signal transmission cell without the equalization unit.

FIG. 5E is an eye pattern of the differential mode signal associated with the signal transmission cell with the equalization unit.

FIG. 6 is an explosive diagram of the signal transmission cell of FIG. 1A.

FIG. 7 is a schematic diagram of an equivalent model associated with the signal transmission cell of FIG. 1A.

FIG. 8A and FIG. 8B are circuit diagrams of two signal transmission cells respectively according to another two exemplary embodiments of the present disclosure.

### DESCRIPTION OF THE EXEMPLARY EMBODIMENTS

Reference will now be made in detail to the exemplary embodiments of the present disclosure, examples of which are illustrated in the accompanying drawings. Wherever possible, the same reference numbers are used in the drawings and the description to refer to the same or similar parts.

Generally speaking, a differential signal (Vᵢₙ₊, Vᵢₙ₋) has a common mode signal V_{c} and a differential mode signal V_{d}, the differential mode signal V_{d} is the difference of the differential signal (Vᵢₙ₊, Vᵢₙ₋), i.e. V_{d}=(Vᵢₙ₊−Vᵢₙ₋)/2, and the common mode signal V_{c} is the average of the differential signal (V_{in +}, Vᵢₙ₋), i.e. V_{c}=(Vᵢₙ₊+Vᵢₙ₋)/2. Thus, the differential signal (Vᵢₙ₊, Vᵢₙ₋) can be expressed as, Vᵢₙ₊=V_{c}+V_{d}, Vᵢₙ₋=V_{c}−V_{d}.

In the signal transmission circuit, assuming the total energy of the common mode signal V, is normalized, the S parameters of the signal transmission circuit can be expressed as, 1=|S_{cc11}|²+|S_{cc21}|²+Loss, wherein |S_{cc11}|² is present of the normalized refection energy of the common mode signal V_{c}, |S_{cc21}|² is present of the normalized transmission energy of the common mode signal V_{c}, and Loss is present of the normalized attenuation energy of the common mode signal V_{c}.

In the differential signal transmission, the common mode signal V_{c} is considered as portion of the noise, and thus is also called common mode noise. If the common mode noise passes through the signal transmission circuit, the common mode noise will affect the differential mode signal V_{d}. Thus, the common mode noise suppression circuit is designed in the signal transmission circuit according to an exemplary embodiment of the present disclosure, so as to make the normalized transmission energy |S_{cc21}|² of the common mode signal V_{c} approach to 0.

Due to the energy conversation, the normalized refection energy |S_{cc11}|² of the common mode signal V_{c} approaches to 1. Thus, to solve the radiation problem due to the reflected common mode noise, an exemplary embodiment of the present disclosure provides a signal transmission circuit to make the normalized attenuation energy (presented by the variable Loss) of the common mode signal V, approach to 1 and the normalized refection energy |S_{cc11}|² of the common mode signal V, approach to 0. Thus, the common mode noise is suppressed, and there is no unexpected radiation problem existed.

In short, an exemplary embodiment of the present disclosure provides a signal transmission circuit with wideband common mode suppression (|S_{cc21}|). The following exemplary embodiments illustrate several implementations of the signal transmission circuits and the signal transmission cells. Besides, the signal transmission circuit is manufactured by the semiconductor process, thus the signal transmission circuit is a nano-scale circuit, and it is easy to vertically integrate the signal transmission circuit in the very-large-scale integration (VLSI) circuit, so as to efficiently save the area which the passive circuit implemented on or in the substrate (such as printed substrate or ceramics substrate).

[Exemplary Embodiment of Signal Transmission Cell]

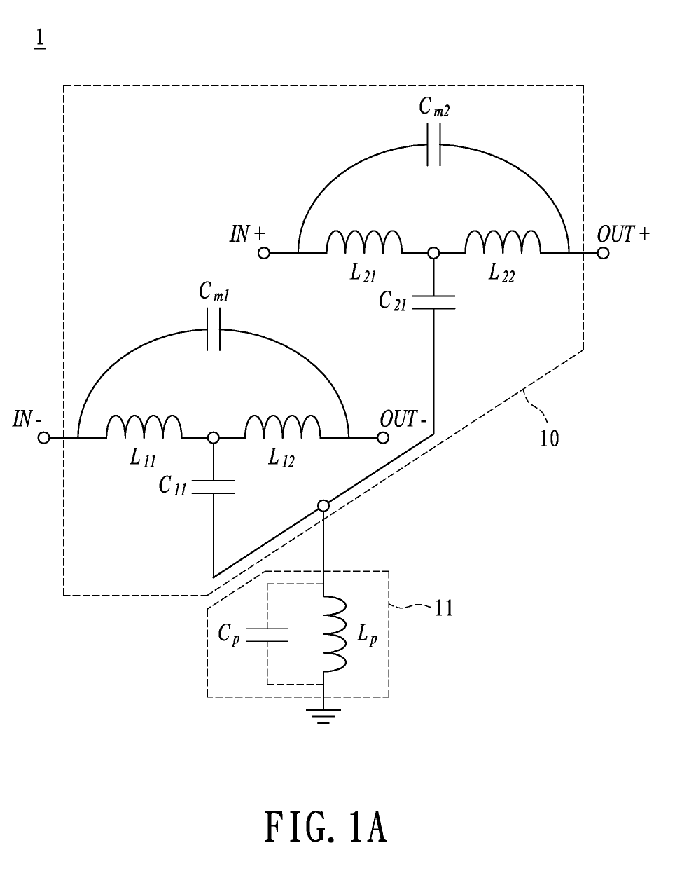

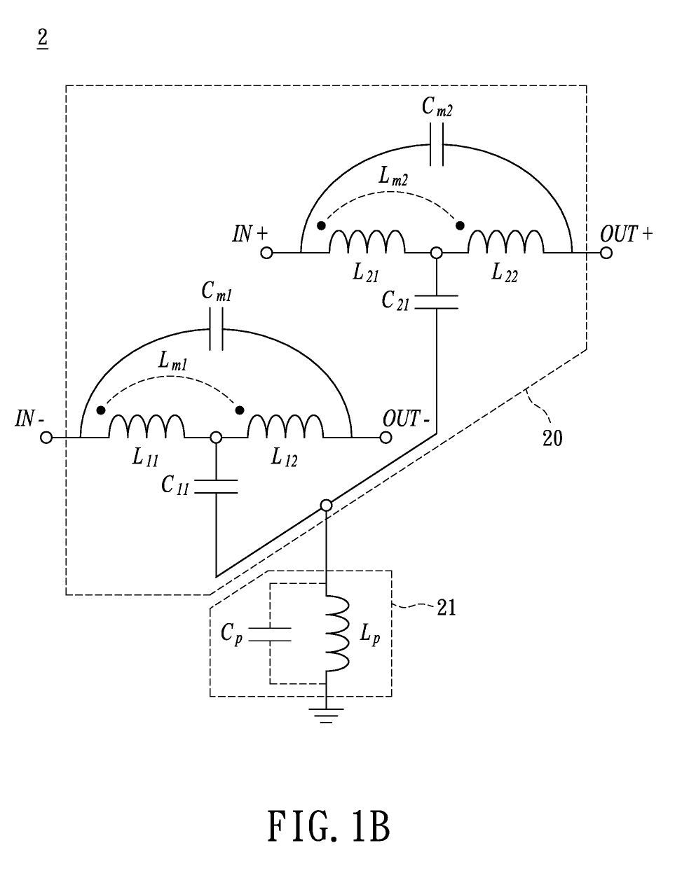

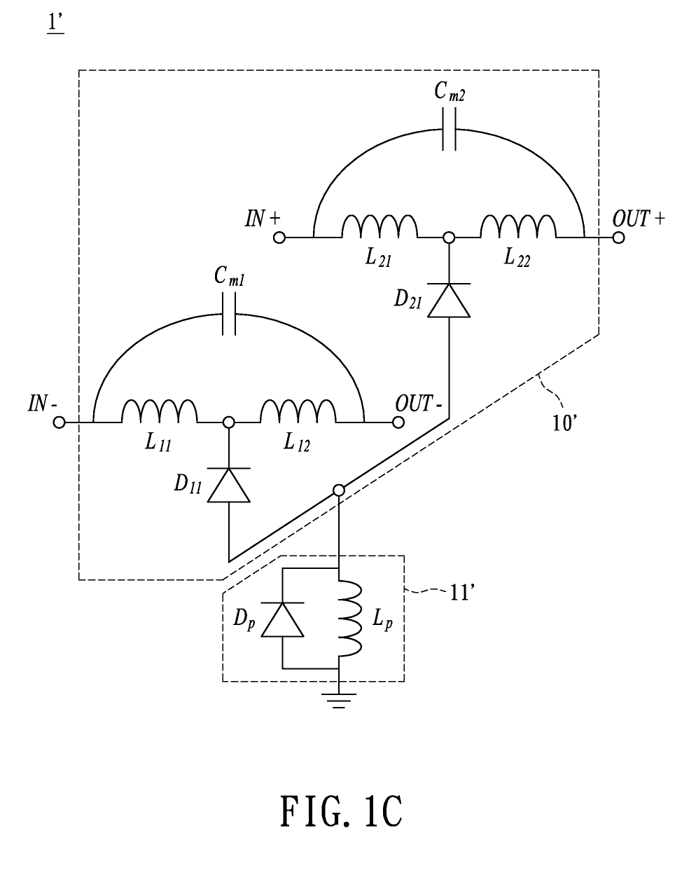

Referring to FIG. 1A, FIG. 1A is a circuit diagram of a signal transmission cell according to an exemplary embodiment of the present disclosure. The signal transmission cell 1 comprises a two-port all pass network 10 and a common mode noise suppression circuit 11, wherein the two-port all pass network 10 is electrically connected to a ground voltage through the common mode noise suppression circuit 11. In the exemplary embodiment, multiple signal transmission cells 1 can be connected in serial fashion to form a signal transmission circuit.

The two-port all pass network 10 has differential signal input ends IN+, IN−, and differential signal output ends OUT+, OUT−. The two-port all pass network 10 receives the differential signal (Vᵢₙ₊, Vᵢₙ₋) via the differential signal input ends IN+, IN−, and outputs the differential signal the differential signal (V′ᵢₙ₊, V′ᵢₙ₋) on the differential signal output ends OUT+, OUT−.

The common mode noise suppression circuit 11 can not affect the transmission of the differential mode signal V_{d}, but can block merely the common mode signal V_{c} (i.e. common mode noise) to be sent to the differential signal output ends OUT+ and OUT−, so as to decrease the effect on the circuit due to the common mode noise. Thus, the common mode noise in the differential signal (V′ᵢₙ₊, V′ᵢₙ₋) can be suppressed, and the differential mode signal V′_{d} in the differential signal (V′ᵢₙ₊, V′ᵢₙ₋) is similar to the differential mode signal V_{d} in the differential signal (Vᵢₙ₊, Vᵢₙ₋). In short, the common mode noise suppression circuit 11 has wideband common mode noise suppression to make the signal transmission cell 1 suppress the effect of common mode noise impacting on the differential mode signal V_{d}, and to faithfully transmit the differential mode signal V_{d} in the differential signal (Vᵢₙ₊, Vᵢₙ₋).

In the exemplary embodiment of FIG. 1A, the two-port all pass network 10 comprises inductors L₁₁, L₁₂, L₂₁, L₂₂, mutual capacitors Cₘ₁, Cₘ₂, and capacitors C₁₁, C₂₁. A first end of the inductor L₁₁ is electrically connected to differential signal input ends IN− and a first end of the mutual capacitor Cₘ₁, a second end of the inductor L₁₁ is electrically connected to a first end of the inductor L₁₂ and a first end of the capacitor C₁₁, and a second end of the inductor L₁₂ is electrically connected to a second end of the mutual capacitor Cₘ₁ and the differential signal output end OUT−. A first end of the inductor L₂₁ is electrically connected to the differential signal input end IN+ and a first end of the mutual capacitor Cₘ₂, a second end of the inductor L₂₁ is electrically connected to a first end of the inductor L₂₂ and a first end of the capacitor C₂₁, and a second end of the inductor L₂₂ is electrically connected to a second end of the mutual capacitor Cₘ₁ and the differential signal output end OUT+. A second end of the capacitor C₁₁ is electrically connected to a second end of the capacitor C₂₁.

In the exemplary embodiment, the inductors L₁₁ and L₁₂ are designed to have no mutual inductors therebetween, i.e. the mutual inductor approaches to zero. In the similar manner, the inductor L₂₁ and L₂₂ are designed to have no mutual inductors therebetween, i.e. the mutual inductor approaches to zero. Therefore, the structure of signal transmission cell 1 is simple, and it is easy to manufacture the signal transmission cell 1 with the lower cost and higher stability. In short, the implementations of the inductors L₁₁, L₁₂, and the capacitors C₁₁, C₂₁ are not used to limit the present disclosure. It is noted that the mutual inductance is prone to be affected by the process variation, and thus the sensitivity of the signal transmission circuit in response to the process variation can be reduced (i.e. the stability is increased) while the mutual inductance is designed to be zero substantially.

In the exemplary embodiment of FIG. 1A, the common mode noise suppression circuit 11 comprises an inductor Lₚ and a capacitor Cₚ. First ends of the inductor Lₚ and the capacitor Cₚ are electrically connected to second ends of the capacitor C₁₁ and C₂₁, and second ends of the inductor Lₚ and the capacitor Cₚ are electrically connected to the ground voltage. In the exemplary embodiment, the capacitor Cₚ can be a parasitic capacitor of the inductor Lₚ, or the existed capacitor formed from some specific design.

It is noted that, the implementations of the two-port all pass network 10 and the common mode noise suppression circuit 11 associated with the signal transmission cell 1 are not used to limit the present disclosure. That is, the two-port all pass network 10 can be the other type of the two-port all pass network, and the common mode noise suppression circuit 11 can further has a resistor.

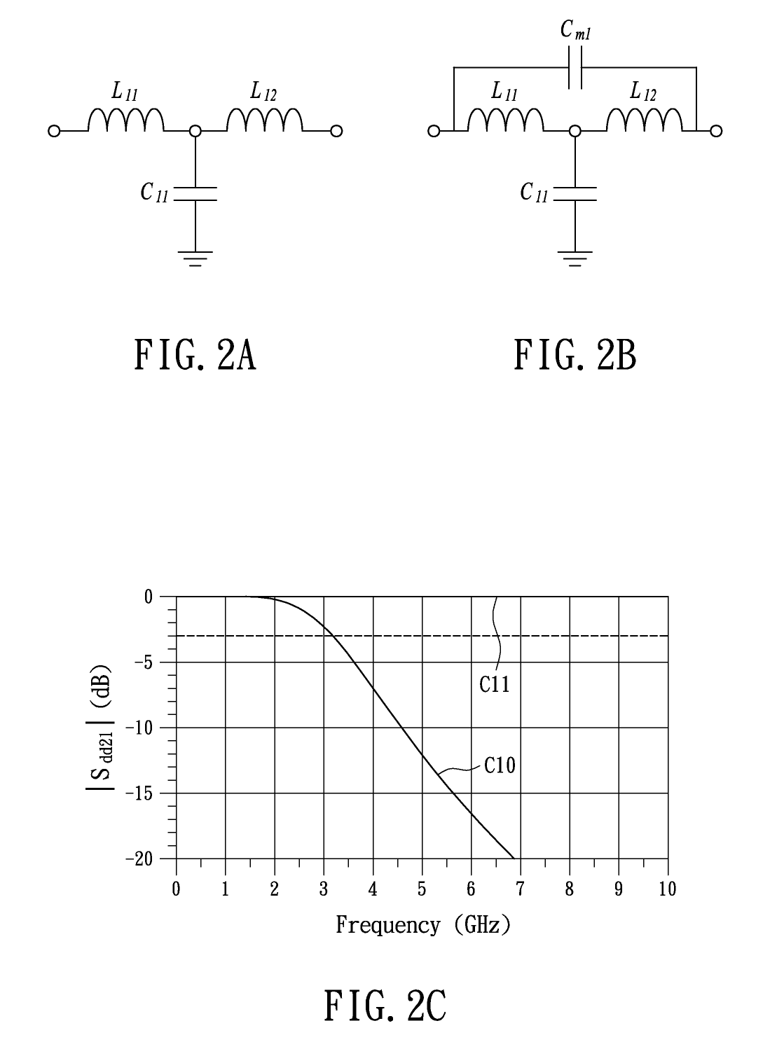

Next, referring to FIG. 2A through FIG. 2C, FIG. 2A is a circuit diagram of a differential mode half circuit of a signal transmission cell of FIG. 1A which the mutual capacitors Cₘ₁ and Cₘ₂ are removed, FIG. 2B is a circuit diagram of a differential mode half circuit of a signal transmission cell of FIG. 1A, and FIG. 2C is a curve diagram showing the relation between a frequency and S parameter |S_{dd21}| associated with the signal transmission cell of FIG. 1A and the signal transmission cell of FIG. 1A which the mutual capacitors Cₘ₁ and Cₘ₂ are removed. In FIG. 2C, a curve C10 is present of a curve of a frequency and S parameter |S_{dd21}| associated with the signal transmission cell of FIG. 1A which the mutual capacitors Cₘ₁ and Cₘ₂ are removed, and a curve C11 is present of a curve of a frequency and S parameter |S_{dd21}| associated with the signal transmission cell of FIG. 1A.

From the observation of the curves C10 and C11, the mutual capacitors Cₘ₁ and Cₘ₂ of the signal transmission cell 1 in FIG. 1A can be used to increase the transmission bandwidth of the differential mode signal V_{d}. Taking the −3 dB bandwidth as the transmission bandwidth, if the mutual capacitors Cₘ₁ and Cₘ₂ are not added, the transmission bandwidth of the differential mode signal V_{d} associated with the signal transmission cell is merely 0 through 3.2 GHz; however, if the mutual capacitors Cₘ₁ and Cₘ₂ are added, the transmission bandwidth of the differential mode signal V_{d} associated with the signal transmission cell 1 is increased to more than 10 GHz.

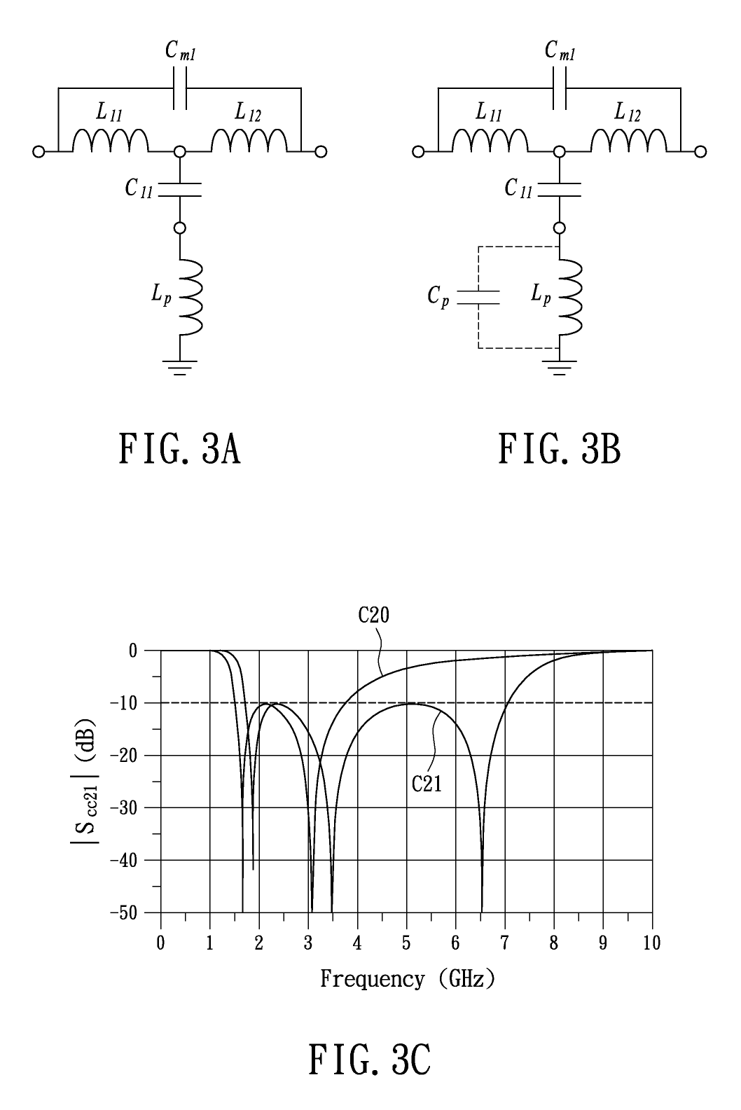

Next, referring to FIG. 3A through FIG. 3C, FIG. 3A is a circuit diagram of a common mode half circuit of a signal transmission cell of FIG. 1A which the capacitor Cₚ is removed, FIG. 3B is a circuit diagram of a common mode half circuit of a signal transmission cell of FIG. 1A, and FIG. 3C is a curve diagram showing the relation between a frequency and S parameter |S_{cc21}| associated with the signal transmission cell of FIG. 1A and the signal transmission cell of FIG. 1A which the capacitor Cₚ is removed. In FIG. 3C, a curve C20 is present of a curve of a frequency and S parameter |S_{cc21}| associated with the signal transmission cell of FIG. 1A which the capacitor Cₚ is removed, and a curve C21 is present of a curve of a frequency and S parameter |S_{cc21}| associated with the signal transmission cell of FIG. 1A.

From the observation of the curves C20 and C21, the capacitor Cₚ of the signal transmission cell 1 in FIG. 1A can be used to increase the suppression bandwidth of the common mode signal V_{c}. Taking the −10 dB bandwidth as the transmission bandwidth, if the capacitor Cₚ is not added, the suppression bandwidth of the common mode signal V_{c} associated with the signal transmission cell is merely 1.5 GHz through 3.8 GHz; however, if the capacitor Cₚ is added, the suppression bandwidth of the common mode signal V_{c} associated with the signal transmission cell 1 is increased to 1.7 GHz through 7 GHz.

[Another Exemplary Embodiment of Signal Transmission Cell]

Referring to FIG. 1B, FIG. 1B is a circuit diagram of a signal transmission cell according to another exemplary embodiment of the present disclosure. The signal transmission cell 2 in FIG. 1B can also be used to form the signal transmission circuit, and the common mode noise suppression circuit 21 is similar to the common mode noise suppression circuit 11 in FIG. 1A. Compared to the two-port all pass network 10 in FIG. 1A, the inductors L₁₁ and L₁₂ of the two-port all pass network 20 are designed to have a mutual inductor Lₘ₁ therebetween, and in the similar manner, the inductors L₂₁ and L₂₂ are designed to have a mutual inductor Lₘ₂ therebetween.

[Another Exemplary Embodiment of Signal Transmission Cell]

Referring to FIG. 1C, FIG. 1C is a circuit diagram of a signal transmission cell according to another exemplary embodiment of the present disclosure. The signal transmission cell 1′ in FIG. 1C can also be used to form the signal transmission circuit, and the two-port all pass network 10′ and the common mode noise suppression circuit 11′ use diodes D₁₁, D₂₁, and Dₚ to replace the capacitors C₁₁, C₂₁, and Cₚ. Cathodes and anodes of the diodes D₁₁, D₂₁, Dₚ are respectively the first ends and second ends of the capacitors C₁₁, C₂₁, and Cₚ.

[Another two Exemplary Embodiments of Signal Transmission Cells]

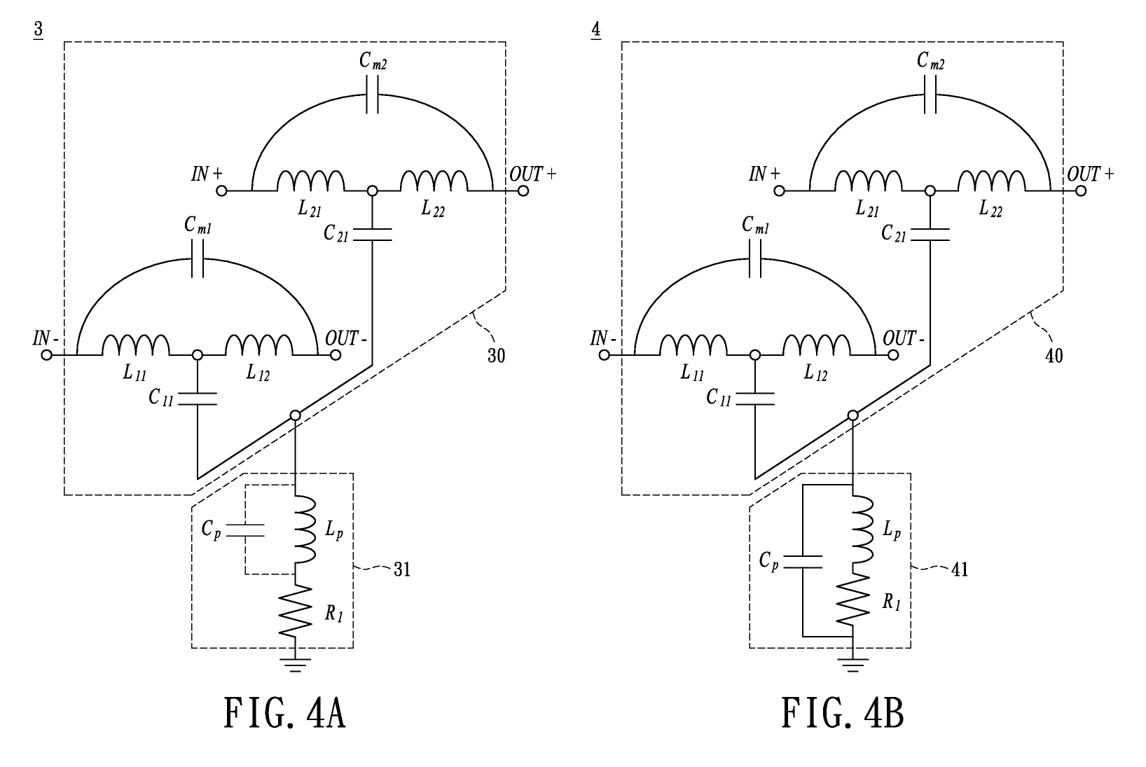

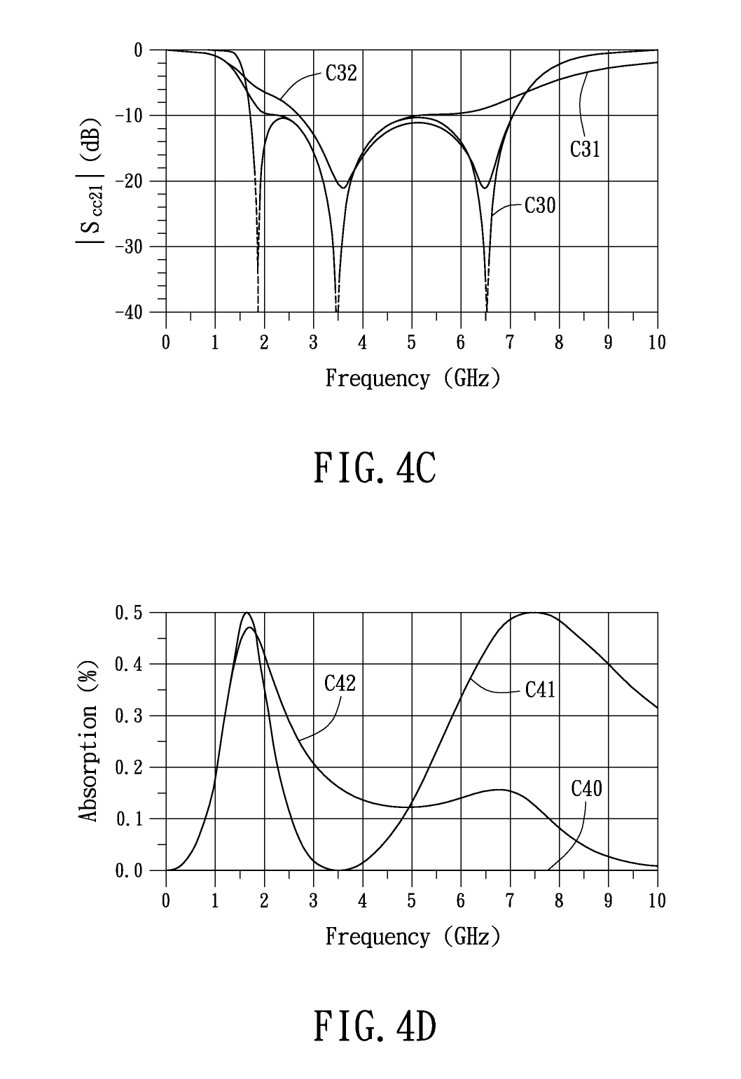

Referring to FIG. 4A and FIG. 4B, FIG. 4A and FIG. 4B are circuit diagrams of two signal transmission cells respectively according to another two exemplary embodiments of the present disclosure. The signal transmission cells 3 and 4 respectively in FIG. 4A and FIG. 4B can also be used to form the signal transmission circuit, and the two-port all pass networks 30 and 40 are similar to the two-port all pass network 10 in FIG. 1A. Compared to the common mode noise suppression circuit 11 in FIG. 1A, the common mode noise suppression circuit 31 in FIG. 4A further comprises a resistor R₁, wherein a first end of the resistor R₁ is electrically connected to second ends of the capacitor Cₚ and inductor Lₚ, and a second end of the resistor R₁ is electrically connected to the ground voltage. In addition, compared to the common mode noise suppression circuit 11 in FIG. 1A, the common mode noise suppression circuit 41 in FIG. 4B also has a resistor R₁, however, a first end of the resistor R₁ is electrically connected to a second end of the inductor Lₚ, and second ends of the resistor R₁ and the capacitor Cₚ are electrically connected to the ground voltage.

The resistor R₁ is for example the attenuating metal wire or plate. The resistor R₁ is used to absorb and attenuate the common mode noise, so as to avoid the unexpected radiation problem due to the reflected the common mode noise. In short, the capacitor Cₚ and inductor Lₚ are used to make normalized transmission energy |S_{cc21}|² approach to 0, and the resistor R₁ is used to make the normalized reflection energy |S_{cc11}|² approach to 0.

Next, referring to FIG. 4C and FIG. 4D, FIG. 4C is a curve diagram showing the relation between a frequency and S parameter |S_{cc21}| associated with the signal transmission cells of FIG. 1A, FIG. 4A, and FIG. 4B, and FIG. 4D is a curve diagram showing the relation between a frequency and an absorption associated with the signal transmission cells of FIG. 1A, FIG. 4A, and FIG. 4B. In FIG. 4C, a curve C30 is present of a frequency and a S parameter |S_{cc21}| associated with the signal transmission cell 1 in FIG. 1A, a curve C31 is present of a frequency and a S parameter |S_{cc21}| associated with the signal transmission cell 3 in FIG. 4A, and a curve C32 is present of a frequency and a S parameter |S_{cc21}| associated with the signal transmission cell 4 in FIG. 4B. In FIG. 4D, a curve C40 is present of a frequency and absorption associated with the signal transmission cell 1 in FIG. 1A, a curve C41 is present of a frequency and absorption associated with the signal transmission cell 3 in FIG. 4A, and a curve C42 is present of a frequency and absorption associated with the signal transmission cell 4 in FIG. 4B.

From the observation of the curves C30 through C32 and C40 through C42, though the addition of the resistor R1 slightly lowers the −10 dB suppression bandwidth of the common mode signal V_{c}, the resistor R1 can absorb and attenuate the common mode noise, such that the unexpected radiation problem due to the reflected common mode noise can be further decreased.

[Another Three Exemplary Embodiments of Signal Transmission Cells]

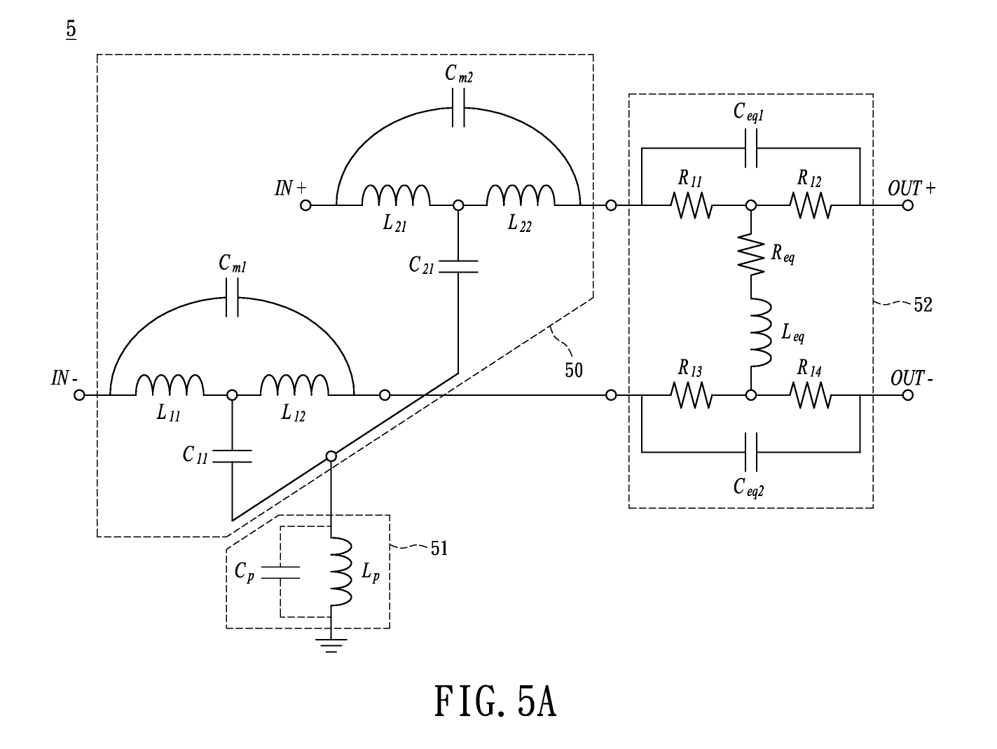

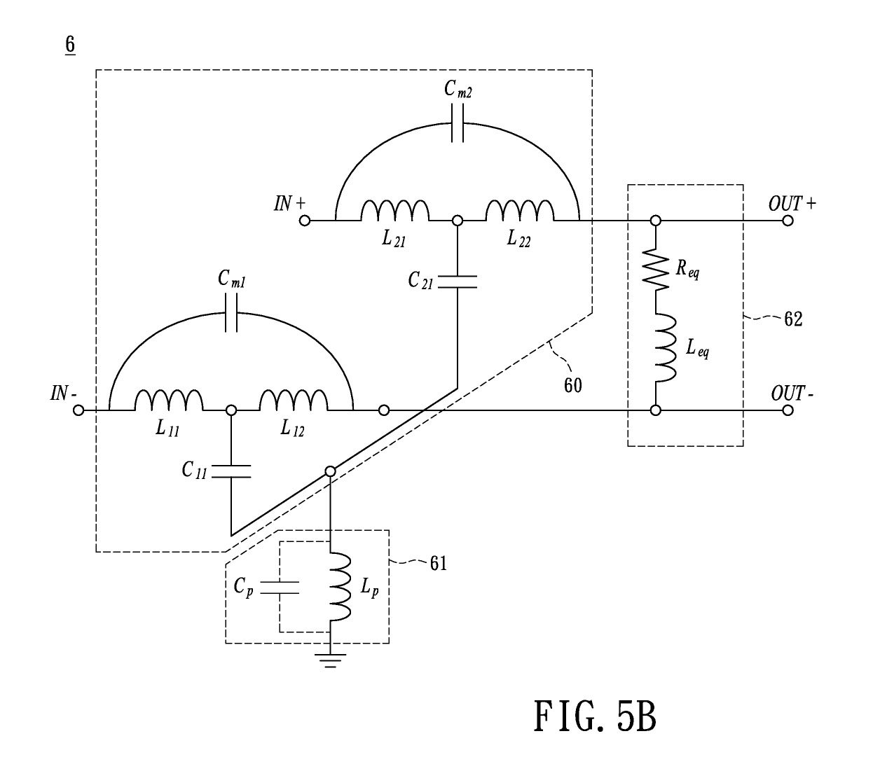

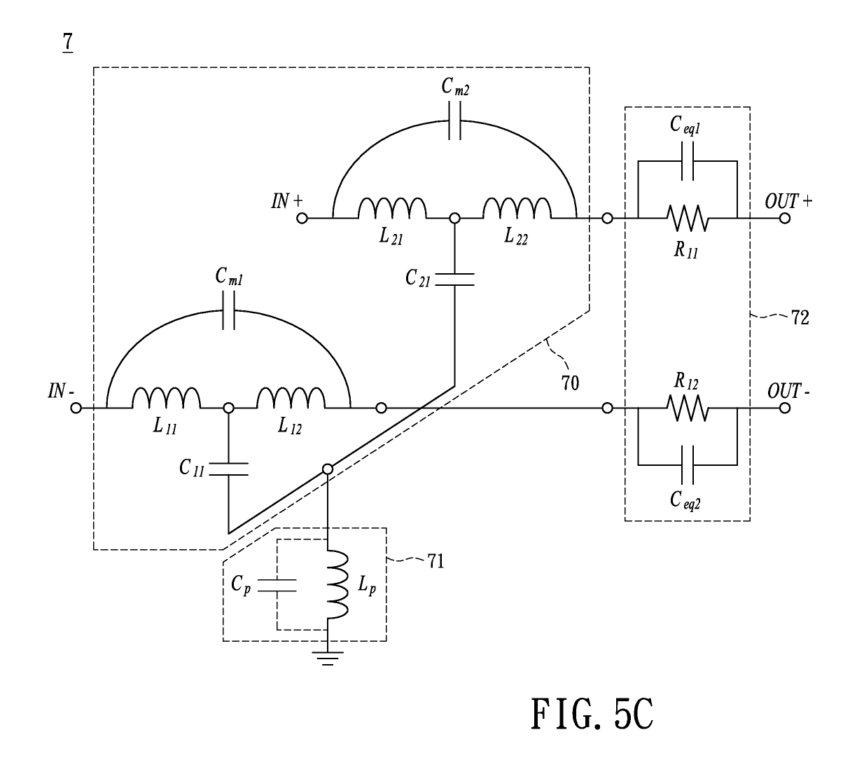

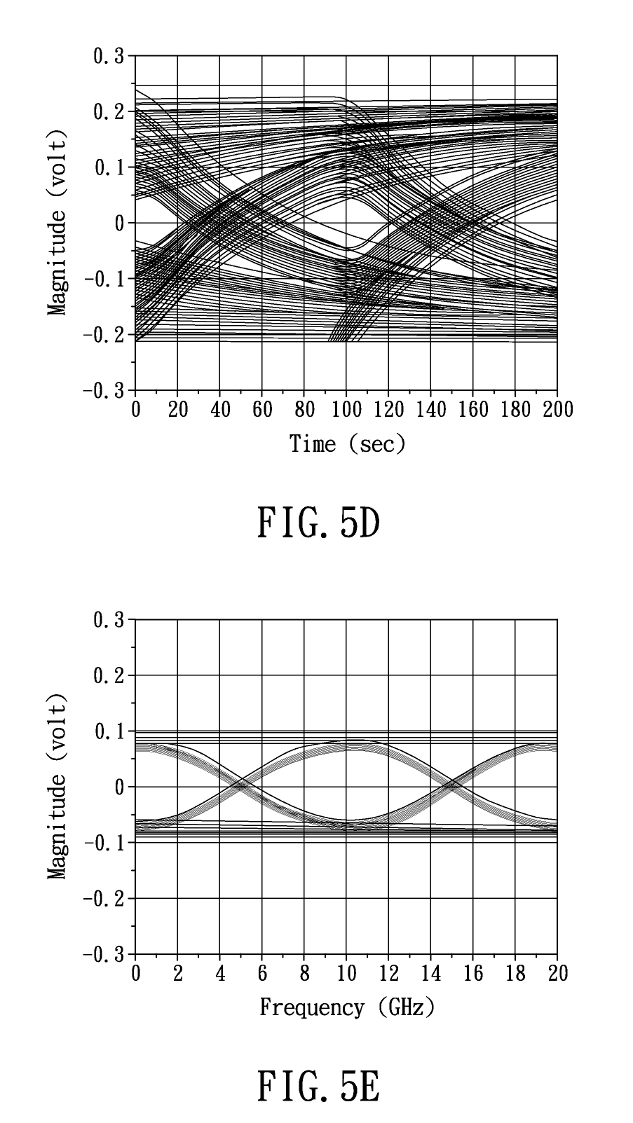

Referring to FIG. 5A through FIG. 5C, FIG. 5A through FIG. 5C are circuit diagrams of three signal transmission cells respectively according to another three exemplary embodiments of the present disclosure. The two-port all pass networks 50, 60, 70 and the common mode noise suppression circuits 51, 61, 71 in the signal transmission cells 5 through 7 are respectively similar to the two-port all pass network 10 and the common mode noise suppression circuit 11 in FIG. 1A. Compared to the signal transmission cell 1 in FIG. 1A, the signal transmission cells 5 through 7 in FIG. 5A through FIG. 5C respectively further comprises equalization units 52, 62, 72. The equalization units 52, 62, 72 are used to improve the signal quality of the differential mode signal V_{d}, so as to enhance the eye pattern of the differential mode V_{d} (the eye pattern dispreads more widely).

In FIG. 5A, the equalization unit 52 is a RLC equalizer. The equalization unit 52 comprises resistors R₁₁ through R₁₄, R_{eq}, capacitors, C_{eq1}, C_{eq2} and inductors L_{eq}. A first end of the resistor R₁₁ is electrically connected to a first output end of the two-port all pass network 50, a second end of the resistor R₁₁ is electrically connected to first ends of the resistor R₁₂, R_{eq}, a second end of the resistor R₁₂ is electrically connected to the differential signal output end OUT+, and two ends of the capacitor C_{eq1} are respectively electrically connected to first output end of two-port all pass network 50 and the differential signal output end OUT+. A second end of the resistor R_{eq} is electrically connected to a first end of the inductor L_{eq}. A first end of the resistor R₁₃ is electrically connected to a second output end of the two-port all pass network 50, a second end of the resistor R₁₃ is electrically connected to a first end of the resistor R₁₄ and a second end of the inductor L_{eq}, a second end of the resistor R₁₄ is electrically connected to the differential signal output end OUT−, and two ends of the capacitor C_{eq2} are respectively electrically connected to a second output end of the two-port all pass network 50 and the differential signal output end OUT−.

In FIG. 5B, the equalization unit 62 is a RL type equalizer. The equalization unit 62 comprises a resistor R_{eq} and an inductor L_{eq}. A first end of the resistor R_{eq} is electrically connected to the differential signal output end OUT+, a second end of the resistor R_{eq} is electrically connected to a first end of the inductor L_{eq}, and a second end of the inductor L_{eq} is electrically connected to the differential signal output end OUT−.

In FIG. 5C, the equalization unit 72 is a RC type equalizer. The equalization unit 72 comprises resistors R₁₁, R₁₂, and capacitors C_{eq1}, C_{eq2}. First ends of the resistor R₁₁ and capacitor C_{eq1} are electrically connected a first output end of the two-port all pass network 70, second ends of the resistor R₁₁ and capacitor C_{eq1} are electrically connected to the differential signal output end OUT+, first ends of the resistor R₁₂ and capacitor C_{eq2} are electrically connected to a second output end of the two-port all pass network 70, and second ends of the resistor R₁₂ and capacitor C_{eq2} are electrically connected to the differential signal output end OUT−.

Referring to FIG. 5D and FIG. 5E, FIG. 5D is an eye pattern of the differential mode signal associated with the signal transmission cell without the equalization unit, and FIG. 5E is an eye pattern of the differential mode signal associated with the signal transmission cell with the equalization unit. From the observation of FIG. 5D and FIG. 5E, compared to the eye pattern of the differential mode signal associated with the signal transmission cell without the equalization unit, the eye pattern of the differential signal associated with one of the signal transmission cells in FIG. 5A through FIG. 5C dispreads more widely. In the better case, a 92% improvement of the differential mode signal associated with the signal transmission cell in one of FIG. 5A through FIG. 5C can be obtained. However, according to the different case and circuit design, the eye pattern may have different improvement rate. To sum up, the improvement rate of the eye pattern is not used to limit the present disclosure.

[Exemplary Embodiment of Physical Structure of Signal Transmission Cell]

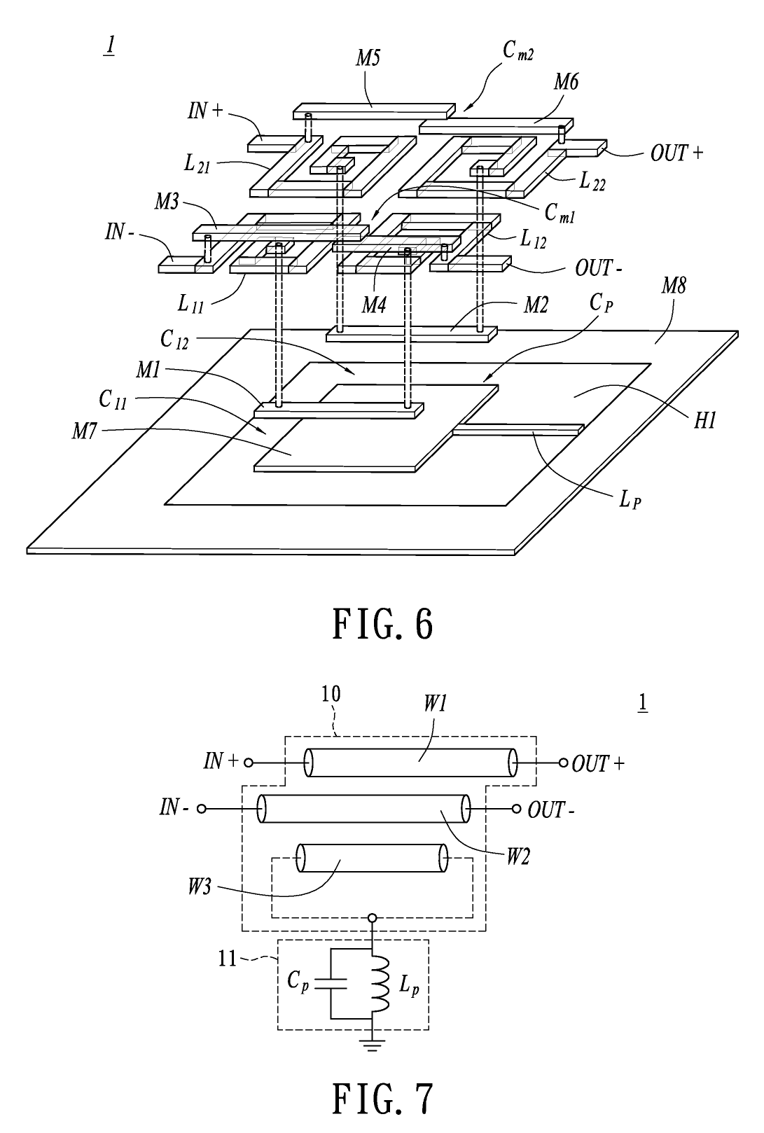

Referring to FIG. 1A and FIG. 6, FIG. 6 is an explosive diagram of the signal transmission cell of FIG. 1A. The physical structure in FIG. 6 can be formed in a substrate by using a semiconductor process, and thus the signal transmission cell 1 in FIG. 1A is benefit of miniaturization, low cost, and easy integration.

The inductors L₁₁, L₁₂, L₂₁, L₂₂ can be form by spiral structured inductors, and the inductors L₁₁ and L₁₂ are electrically connected to each other via the metal conductor M1, and the inductors L₂₁ and L₂₂ are electrically connected to each other via the metal conductor M2. The inductor L₁₁ is electrically connected to the metal conductor M3, the inductor L₁₂ is electrically connected to the metal conductor M4, and the metal conductors M3 and M4 have a specific distance (such as the vertical or horizontal specific distance) therebetween, so as to form the mutual capacitor Cₘ₁. The inductor L₂₁ is electrically connected to the metal conductor M5, the inductor L₂₂ is electrically connected to the metal conductor M6, and the metal conductors M5 and M6 have a specific distance (such as the vertical or horizontal specific distance) therebetween, so as to form the mutual capacitor C. In addition, the metal conductors M1 and M7 form the capacitor C₁₁, and the metal conductors M2 and M7 form the capacitor C₁₂.

The metal conductor M7 and the metal conductor M8 electrically connected to the ground voltage have a defected ground structure H1 therebetween, and have a gap, so as to form the capacitor Cₚ. Additionally, the inductor Lₚ is electrically connected between the metal conductors M7 and M8, and is located in the defected ground structure H1, such that the inductor Lₚ and the capacitor Cₚ can be connected in parallel to form the common mode noise suppression circuit 11 as shown in FIG. 1A.

[Equivalent Model of Signal Transmission Cell]

Referring to FIG. 7 and FIG. 1A, FIG. 7 is a schematic diagram of an equivalent model associated with the signal transmission cell of FIG. 1A. In the signal transmission cell of FIG. 1A, the two-port all pass network 10 can equivalent to three conductors W1 through W3, wherein the conductors W1 and W3 form the first transmission circuit, and the conductors W2 and W3 form the second transmission circuit. The signals conveyed on the first transmission circuit and the second transmission circuit have the same magnitudes and opposite phases, and thus the first transmission circuit and the second transmission circuit form a pair of differential transmission lines. The common mode noise suppression circuit 11 is electrically connected to the conductor W3, and has the common mode noise suppression by using effects of the capacitor Cₚ and the inductor Lₚ. It is noted that the common mode noise suppression circuit 11 can be electrically connected to any end of the conductor W3, or the common mode noise suppression circuit 11 can be electrically connected to the two ends of conductor W3 as shown in FIG. 7.

It is noted that, a differential mode impedance and common mode impedance of the two-port all pass network 10 formed by the conductors W1 through W3 in the exemplary embodiment can be respectively about 70 through 120 ohms and 20 through 50 ohms. In a better case, the formed differential mode impedance and the formed common mode impedance are respectively 70 through 120 ohms and 20 through 50 ohms. However, the ranges of the above impedances are not used to limit the present disclosure.

In addition, the conductors W1 and W2 therebetween are designed to have coupling, but the present disclosure is not limited thereto. In another exemplary embodiment, the conductors W1 and W2 therebetween are designed to have no coupling substantially, and that is the coupling amount of the conductors W1 and W2 therebetween approached to 0. Besides, in the exemplary embodiment of the present disclosure, the lengths of the conductors W1 and W2 are the same, the impedances of the conductors W1 and W2 are the same, too, and even the types of the conductors W1 and W2 are the same. For example, if the conductor W1 is a microstrip conductor, the conductor W2 can be a microstrip conductor; if the conductor W1 is a strip conductor, the conductor W2 can be a strip conductor. To sum up, the types of the conductors W1 and W2 are not used to limit the present disclosure, the other types of the conductors, such as coaxial cable, co-planar waveguide, slot waveguide, twist pair cable, and other waveguide can be used in the present disclosure.

[Another Two Exemplary Embodiments of Signal Transmission Cells]

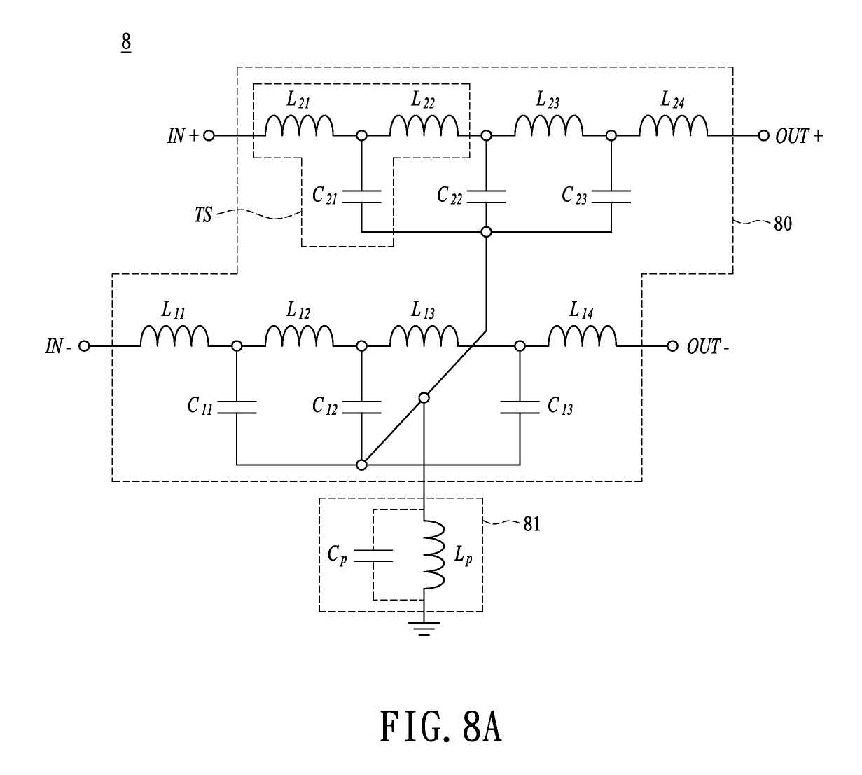

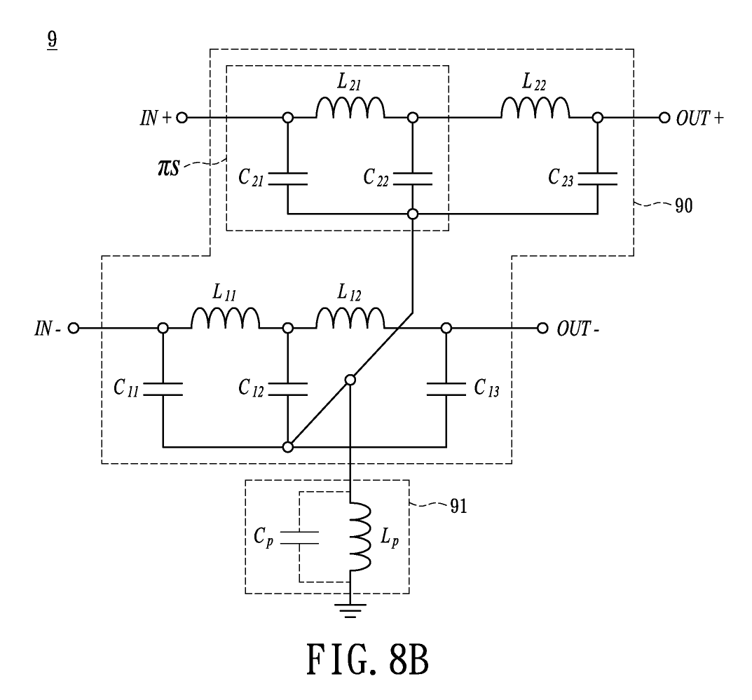

Referring to FIG. 8A and FIG. 8B, FIG. 8A and FIG. 8B are circuit diagrams of two signal transmission cells respectively according to another two exemplary embodiments of the present disclosure. The common mode noise suppression circuits 81 and 91 respectively of the signal transmission cells 8 and 9 are the same as the common mode noise suppression circuit 11 in FIG. 1A.

In FIG. 8A, the two-port all pass network 80 comprises inductors L₁₁ through L₂₄ and capacitors C₁₁ through C₂₃, wherein the inductors L₂₁, L₂₂, and the capacitor C₂₁ form a T-shaped circuit structure TS, the two-port all pass network 80 can be formed by multiple T-shaped circuit structures TS (in FIG. 8A, there are three T-shaped circuit structures TS in the upper side, and three T-shaped circuit structures TS in the bottom side), and two neighboring T-shaped circuit structures TS share the same one inductor (such as the inductor L₂₂). In the exemplary embodiment of the present disclosure, regarding the path from the differential signal input end IN+ to the differential signal output end OUT+, the inductors L₂₁ through L₂₄ are connected in the serial fashion, and first ends of the capacitors C₂₁ through C₂₃ are electrically connected to the connection mode of the neighboring serially connected two inductors L₂₁ through L₂₄. Regarding the path from the differential signal input end IN− to the differential signal output end OUT−, the inductors L₁₁ through L₁₄ are connected in the serial fashion, and first ends of the capacitors C₁₁ through C₁₃ are electrically connected to the connection mode of the neighboring serially connected two inductors L₁₁ through L₁₄. Second ends of the capacitors C₂₁ through C₂₃ are electrically connected to each other, and second ends of the capacitors C₁₁ through C₁₃ are electrically connected to each other. The second end of the capacitor C₂₂ is further electrically connected to the second end of the capacitor C₁₂, and the second ends of the capacitors C₂₂ and C₁₂ are further electrically connected to one end of the common mode noise suppression circuit 81.

In FIG. 8B, the two-port all pass network 90 comprises inductors L₁₁ through L₂₂ and capacitors C₁₁ through C₂₃, wherein the inductor L₂₁ and capacitors C₂₁, C₂₂ form a π-shaped circuit structure πS, the two-port all pass network 90 are formed by multiple π-shaped circuit structures πS (in FIG. 8B, there are two π-shaped circuit structures πS in the upper side, and two π-shaped circuit structures πS in the bottom side), and two neighboring π-shaped circuit structures πS share the same one capacitor (such the inductor C₂₂). In the exemplary embodiment, regarding the path from the differential signal input end IN+ to the differential signal output end OUT+, the inductors L₂₁ and L₂₂ are connected in the serial fashion, first ends of the capacitors C₂₁, C₂₃ are respectively electrically connected to a first end of the inductor L₂₁ and a second end of the inductor L₂₂, and a first end of the capacitor C₂₂ is electrically connected to a second end of the inductor L₂₁ and a first end of the inductor L₂₂. Regarding the path from the differential signal input end IN− to the differential signal output end OUT−, the inductors L₁₁ and L₁₂ are connected in the serial fashion, first ends of the capacitors C₁₁, C₁₃ are respectively electrically connected to a first end of the inductor L₁₁ and a second end of the inductor L₁₂, and a first end of the capacitor C₁₂ is electrically connected to a second end of the inductor L₁₁ and a first end of the inductor L₁₂. Second ends of the capacitor C₂₁ through C₂₃ are electrically connected to each other, and second ends of the capacitors C₁₁ through C₁₃ are electrically connected to each other. Second ends of the capacitors C₂₂ and C₁₂ are electrically connected to each other, and further electrically connected to one end of the common mode noise suppression circuit 91.

[Results of Exemplary Embodiments]

Accordingly, exemplary embodiments of the present disclosure provide a signal transmission circuit and a signal transmission cell thereof. The signal transmission circuit and the signal transmission cell thereof can suppress common mode noise and have a large transmission bandwidth of the differential mode signal. In addition, the signal transmission circuit and the signal transmission cell thereof are benefit of miniaturization, low cost, and easy integration.

The above-mentioned descriptions represent merely the exemplary embodiment of the present disclosure, without any intention to limit the scope of the present disclosure thereto. Various equivalent changes, alternations or modifications based on the claims of present disclosure are all consequently viewed as being embraced by the scope of the present disclosure.

What is claimed is:

1. A signal transmission cell, comprising:
a two-port all pass network, comprising:
a first inductor;
a second inductor, a first end thereof is electrically connected to a second end of the first inductor;
a first mutual capacitor, a first end and a second end thereof are respectively electrically connected to a first end of the first inductor and a second end of the second inductor;
a third inductor;
a fourth inductor, a first end thereof is electrically connected to a second end of the third inductor;
a second mutual capacitor, a first end and a second end thereof are respectively electrically connected to a first end of the third inductor and the second end of the fourth inductor;
a first capacitor, a first end thereof is electrically connected to the first end of the second inductor; and
a second capacitor, a first end thereof is electrically connected to the first end of the fourth inductor, and a second end thereof is electrically connected to a second end of the first capacitor; and
a common mode noise suppression circuit, comprising:
a fifth inductor, a first end thereof is electrically connected to the second end of the first capacitor, and a second end thereof is electrically connected to a ground voltage; and
a third capacitor, a first end thereof is electrically connected to the first end of the fifth inductor, and a second end thereof is electrically connected to a ground voltage.

2. The signal transmission cell according to claim 1, wherein the first capacitor and the second capacitor are two diodes, and two anodes of the two diodes are respectively the two second ends of the first capacitor and the second capacitor, and two cathodes of the of the two diodes are respectively the two first ends of the first capacitor and the second capacitor.

3. The signal transmission cell according to claim 1, wherein a mutual inductance the first inductor and the second inductor is approaching to zero, and a mutual inductance the third inductor and the fourth inductor is approaching to zero.

4. The signal transmission cell according to claim 1, wherein the first inductor and the second inductor have a first mutual inductor therebetween, and the third inductor and the fourth inductor have a second mutual inductor therebetween.

5. The signal transmission cell according to claim 1, wherein the third capacitor is a parasitic capacitor of the fifth inductor.

6. The signal transmission cell according to claim 1, wherein the common mode noise suppression circuit further comprises:
a first resistor, a first end thereof is electrically connected to the second ends of the third capacitor and the fifth inductor, and a second end thereof is electrically connected the ground voltage, wherein the seconds of the third capacitor and the fifth inductor are electrically connected to the ground voltage via the first resistor.

7. The signal transmission cell according to claim 1, wherein the common mode noise suppression circuit further comprises:
a first resistor, a first end thereof is electrically connected to the second end of the fifth inductor, and a second end thereof is electrically connected the ground voltage, wherein the second of the fifth inductor are electrically connected to the ground voltage via the first resistor, and the second of the third capacitor is electrically connected to the ground voltage directly.

8. The signal transmission cell according to claim 1, further comprising:
an equalization unit, two input end thereof are respectively electrically connected to the second ends of the second inductor and the fourth inductor, the equalization unit is used to improve a signal quality of a differential mode signal, and to output a differential signal corresponding to the differential signal on two output ends thereof.

9. The signal transmission cell according to claim 8, wherein the equalization unit further comprises:
a first resistor, a first end thereof is electrically connected to the second end of the second inductor;
a second resistor, a first end thereof is electrically connected to a second end of the first resistor;
a fourth capacitor, a first and second ends thereof are respectively electrically connected to the first end of the first resistor and the second end of the second resistor;
a third resistor, a first end thereof is electrically connected the second end of the fourth inductor;
a fourth resistor, a first end thereof is electrically connected to a first end of the third resistor second;
a fifth capacitor, a first and a second ends thereof are respectively electrically connected to the first end of the third resistor and a second end of the fourth resistor;
a fifth resistor, a first end thereof is electrically connected to the second end of the first resistor; and
a sixth inductor, a first end thereof is electrically connected to a second end of the fifth resistor, a second end thereof is electrically the second end of the third resistor.

10. The signal transmission cell according to claim 8, wherein the equalization unit comprises:
a first resistor, a first end thereof is electrically connected to the second end of the second inductor;
a sixth inductor, a first end thereof is electrically connected to a second end of the first resistor, a second end thereof is electrically connected to the second end of the fourth inductor.

11. The signal transmission cell according to claim 8, wherein the equalization unit comprises:
a first resistor, a first end thereof is electrically connected to the second end of the second inductor;
a fourth capacitor, a first and a second ends thereof are respectively electrically connected to a first and the second end of the first resistor;
a second resistor, a first end thereof is electrically connected to the second end of the fourth inductor; and
a fifth capacitor, a first and a second ends thereof are respectively electrically connected to a first and the second end of the second resistor.

12. A signal transmission cell, comprising:
a first conductor;
a second conductor;
a third conductor, wherein the first conductor and the third conductor form a first transmission circuit, and the second conductor and the third conductor form a second transmission circuit, signals which are respectively conveyed on the first transmission circuit and the second transmission circuit have the same magnitude, but have the opposite phases to each other, so as to form a pair of differential transmission lines;
an inductor, a first end thereof is electrically connected to third conductor, and
a second end thereof is electrically connected to a ground voltage; and
a capacitor, a first end thereof is electrically connected to the first end of the inductor, a second end thereof is electrically connected to the second end of the inductor.

13. The signal transmission cell according to claim 12, wherein a differential mode impedance of the differential transmission lines is about 70 through 120 ohms.

14. The signal transmission cell according to claim 12, wherein a common mode impedance of the differential transmission lines is about 20 through 50 ohms.

15. The signal transmission cell according to claim 12, wherein the first and the second conductors have the same lengths and impedances.

16. The signal transmission cell according to claim 12, wherein types of the first and the second conductors are the same.

17. The signal transmission cell according to claim 12, wherein the first and the second conductors have no coupling therebetween.

18. The signal transmission cell according to claim 12, wherein the first and the second conductors have coupling therebetween.

19. A signal transmission circuit, comprising:
at least one signal transmission cells according to claim 1.

20. A signal transmission circuit, comprising:
at least one signal transmission cells according to claim 12.
